(19) United States
(12) Patent Application Publication
(10) Pub. No.: US 2016/0058190 A1
(43) Pub. Date: Mar. 3, 2016

(54) VIDEO DISPLAY UNIT AND MOUNTING UNIT

(71) Applicants: Kabushiki Kaisha Toshiba, Tokyo (JP); Toshiba Lifestyle Products & Services Corporation, Tokyo (JP)

(72) Inventors: Keisuke Harita, Ome Tokyo (JP); Masahiro Hirano, Fussa Tokyo (JP)

(21) Appl. No.: 14/676,273

(22) Filed: Apr. 1, 2015

(30) Foreign Application Priority Data
Sep. 3, 2014 (JP) 2014-179317

(51) Int. Cl. A47B 97/00; H05K 5/00; H05K 5/02; F16M 13/02

(52) U.S. Cl. CPC A47B 97/001; F16M 13/022; H05K 5/0017; H05K 5/0204

(57) ABSTRACT

According to one embodiment, a mounting unit comprises a first member fixed to a vertical mounting surface and a second member fixed to a back cover of a video display apparatus. The first member comprises a first plate substantially parallel to the mounting surface and a cutout which is provided in the first plate and is opened upward. The second member comprises a second plate which is guided by an inner peripheral surface of the cutout to be rotatable inside the cutout, and a third plate inserted between the first plate and the mounting surface, and is attachable to and detachable from the first member.

### CROSS-REFERENCE TO RELATED APPLICATIONS

This application is based upon and claims the benefit of priority from Japanese Patent Application No. 2014-179317, filed Sep. 3, 2014, the entire contents of which are incorporated herein by reference.

### FIELD

Embodiments described herein relate generally to a video display unit and a mounting unit.

### BACKGROUND

There has been proposed a display for which the user can effect switching between a horizontally extending screen and a vertically extending screen.

With respect to a video display unit, there is a demand for the thickness including a mounting unit to be reduced.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a front view illustrating a video display unit according to a first embodiment;

FIG. 2 is a perspective view illustrating the back of a video display apparatus shown in FIG. 1;

FIG. 3 is a side view illustrating the video display unit shown in FIG. 1;

FIG. 4 is a perspective view illustrating a mounting unit shown in FIG. 1, which is partly disassembled;

FIG. 5 is a sectional view illustrating the mounting unit shown in FIG. 1, which is partly disassembled;

FIG. 6 is a perspective view illustrating a second member shown in FIG. 4, which is disassembled;

FIG. 7 is a perspective view illustrating an assembled state of the mounting unit shown in FIG. 1;

FIG. 8 is a sectional view illustrating an assembled state of the mounting unit shown in FIG. 1;

FIG. 9 is a front view illustrating a change of orientation of the video display apparatus shown in FIG. 1;

FIG. 10 is a sectional view illustrating the relationship between a cutout and a second plate in a first orientation of the video display apparatus shown in FIG. 1;

FIG. 11 is a sectional view illustrating the relationship between the cutout and the second plate in a second orientation of the video display apparatus shown in FIG. 1;

FIG. 12 is a perspective view illustrating a first member according to a second embodiment;

FIG. 13 is a back view illustrating a mounting unit according to a third embodiment;

FIG. 14 is a back view illustrating a mounting unit according to a fourth embodiment; and

FIG. 15 is a back view illustrating a mounting unit according to a fifth embodiment.

### DETAILED DESCRIPTION

Various embodiments will be described hereinafter with reference to the accompanying drawings.

In general, according to one embodiment, a mounting unit comprises a first member fixed to a vertical mounting surface and a second member fixed to a back cover of a video display apparatus. The first member comprises a first plate substantially parallel to the mounting surface and a cutout which is provided in the first plate and is opened upward. The second member comprises a second plate which is guided by an inner peripheral surface of the cutout to be rotatable inside the cutout, and a third plate inserted between the first plate and the mounting surface, and is attachable to and detachable from the first member.

In this specification, some elements are each expressed by two or more terms. These terms are merely examples and the above-mentioned elements may be expressed by another or other terms. The other elements, which are not expressed by two or more terms, may be expressed by another or other terms.

Also, the drawings are merely examples, and may differ from when the embodiments are actually realized in terms of, for example, the relationship between thickness and planar dimension and the ratio of thickness of layers. Further, in the drawings, the relationship or ratio of dimensions may be different from figure to figure.

### First Embodiment

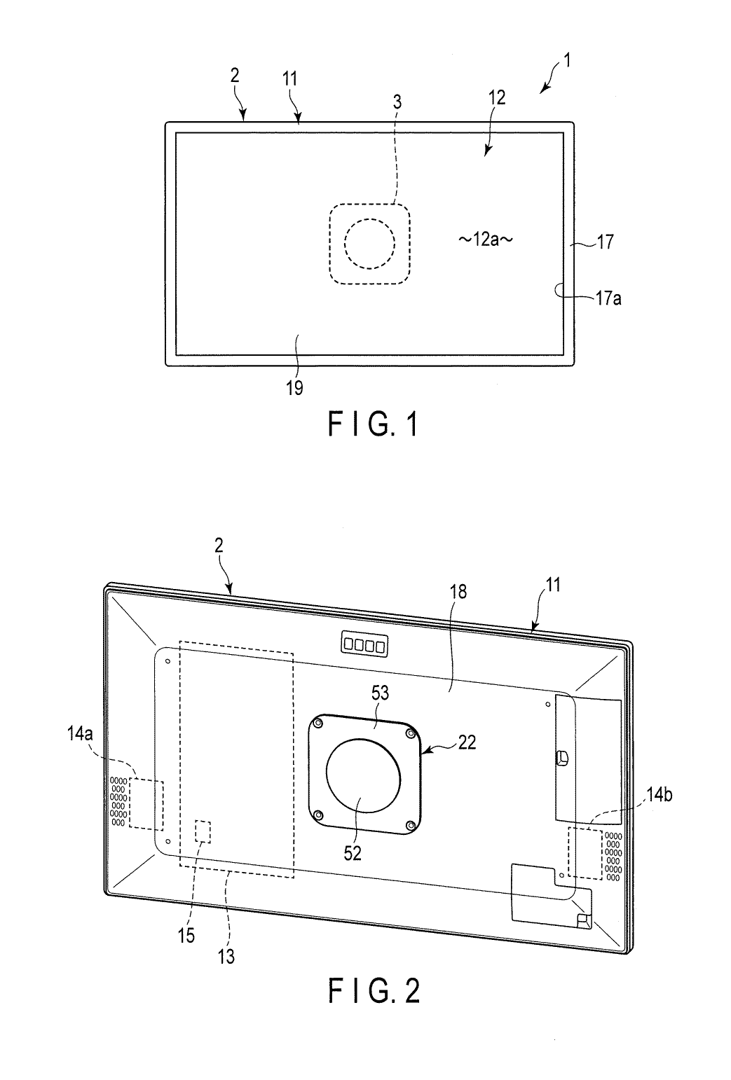

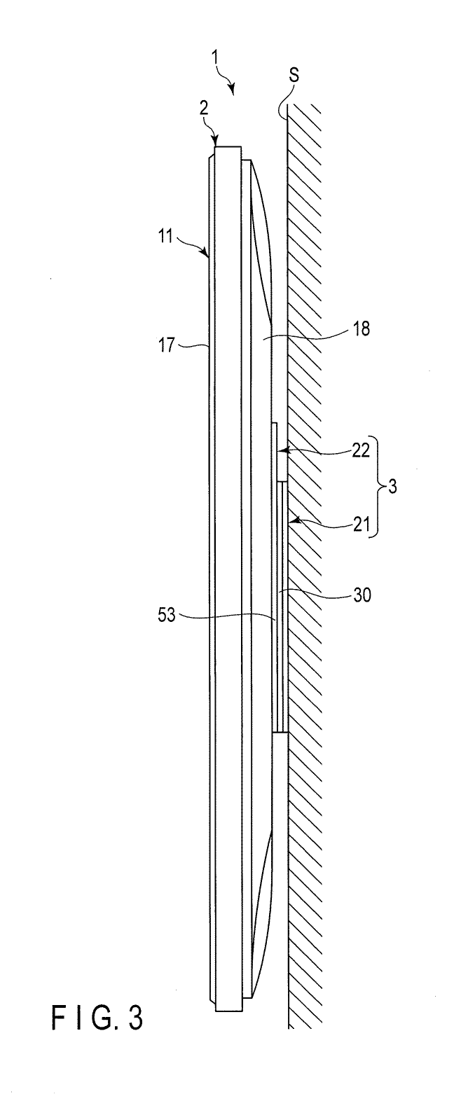

FIG. 1 to FIG. 11 show a video display unit 1 according to a first embodiment. The video display unit 1 according to the present embodiment is a so-called wall-hung type, and can be used, for example, being mounted on a vertical mounting surface S (see FIG. 3). The mounting surface S is, for example, an indoor wall, but is not limited to this, and may be, for example, an outdoor wall, an outdoor or indoor pillar, or another place.

As shown in FIG. 1 to FIG. 3, the video display unit 1 includes a video display apparatus 2 (display unit main body) and a mounting unit 3 by which the video display apparatus 2 is mounted on the mounting surface S. The video display apparatus 2 is, for example, a tablet terminal (multifunctional portable terminal), but is not limited to this, and may be, for example, an apparatus such as a television, a smartphone or a monitor.

As shown in FIG. 1 and FIG. 2, the video display apparatus 2 comprises a housing 11, and a display 12, a circuit board 13, speakers 14a and 14b and an acceleration sensor 15, which are each accommodated in the housing 11. The housing 11 comprises a front cover 17 (front bezel) and a back cover 18 (unit cover). The front cover 17 is provided with an opening 17a which is formed in the shape of a frame and exposes a display screen 12a of the display 12 to the outside. On the other hand, the back cover 18 is located behind the display 12, the circuit board 13, the speakers 14a and 14b, etc. In the present embodiment, the front cover 17 and the back cover 18 are combined, thereby forming the housing 11, which is rectangular and flat. Materials for the front cover 17 and the back cover 18 are not particularly limited, and they may be formed of, for example, materials (for example, metals) having good heat-radiating properties.

The display 12 comprises the display screen 12a which can display an image (including a still image and a moving image). The display 12 is formed in a rectangle, and can display a plurality of images according to the orientation of the display 12 in a switchable manner on the basis of a signal from the acceleration sensor 15, which will be described later. That is, the display 12 can display a first image which is displayed when the display 12 is oriented to extend horizontally and a second image which is displayed when the display 12 is oriented to extend vertically in a switchable manner.

The display 12, for example, comprises the display screen 12a, which is 24 inches or 32 inches in size, but may be smaller or larger than this. In addition, the display 12 comprises a touchsensor 19 (film sensor) superposed on the display screen 12a, and may be provided as a display to which information can be input from the display screen 12a by operating the display screen 12a with a finger or a tablet pen.

The circuit board 13 is a main board of the video display apparatus 2 equipped with, for example, a CPU. The circuit board 13 is an example of each of a controller and a control board, and comprehensively controls the operations of the display 12 and the speakers 14a and 14b. The circuit board 13 automatically switches an image to be displayed on the display 12 in accordance with the orientation of the display 12, for example, on the basis of a signal from the acceleration sensor 15.

The speakers 14a and 14b are located between the display 12 and the back cover 18, and are separately disposed, for example, at a pair of ends in a longitudinal direction of the housing 11. The acceleration sensor 15 detects the orientation (direction in a longitudinal direction) of the display 12. The acceleration sensor 15 is an example of a detector which detects the orientation of the display 12 (the orientation of the video display apparatus 2).

Next, the mounting unit 3 will be described with reference to FIG. 3 to FIG. 11.

As shown in FIG. 3, the mounting unit 3 (wall-hung unit) is fixed to the back cover 18 of the video display apparatus 2, and is located between the video display apparatus 2 and the mounting surface S. The mounting unit 3 is fixed to the mounting surface S to hold the video display apparatus 2 on the mounting surface S, and comprises a rotation mechanism which supports the video display apparatus 2 to make the video display apparatus 2 rotatable. The mounting unit 3 according to the present embodiment is formed by combining a plurality of (for example, four) plate materials.

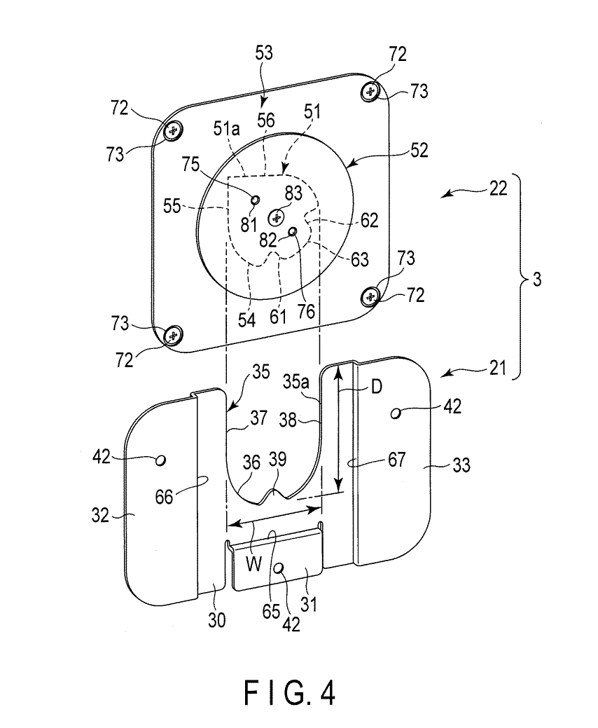

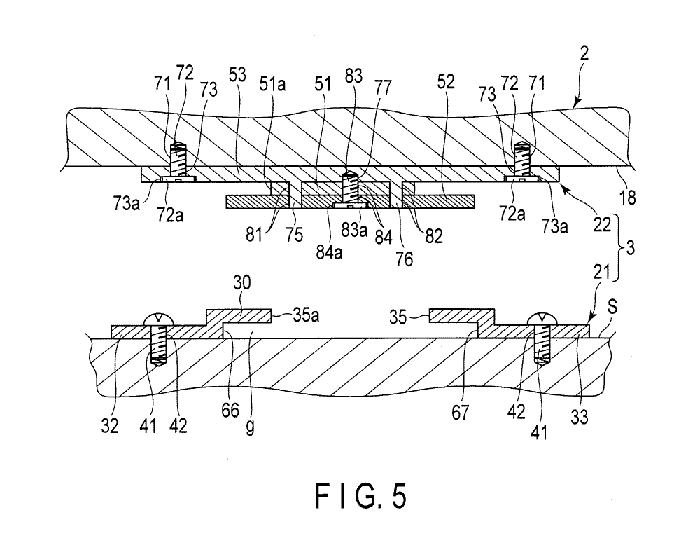

FIG. 4 and FIG. 5 show details of the mounting unit 3. The mounting unit 3 comprises a first member 21 fixed to the mounting surface S and a second member 22 fixed to the video display apparatus 2. The second member 22 is attachable to and detachable from the first member 21.

The first member 21 comprises a first plate 30, a first fixing portion 31, and a pair of second fixing portions 32 and 33. The first plate 30 is disposed substantially parallel to the mounting surface S. The first plate 30 is separated from the mounting surface S by a predetermined space, and comprises a gap g (insertion opening) between itself and the mounting surface S.

The first plate 30 comprises a U-shaped cutout 35. The cutout 35 is formed by cutting the first plate 30, penetrates the first plate 30 in the thickness direction of the first plate 30, and is opened upward. The cutout 35, for example, has a depth D in a vertical direction greater than a width W in a horizontal direction.

The cutout 35 comprises an inner peripheral surface 35a formed by a plate thickness of the first plate 30. The inner peripheral surface 35a comprises an arc portion 36 at least at a part thereof. In the present embodiment, the inner peripheral surface 35a comprises the arc portion 36, a first portion 37, a second portion 38, and a projection 39. The arc portion 36 is provided at a lower part of the cutout 35, includes the projection 39 at its intermediate portion, and is provided substantially over a semicircle. The first portion 37 and the second portion 38 are separately located at both ends of the arc portion 36. The first portion 37 and the second portion 38 each extend upward in a straight line from both ends of the arc portion 36, and reach an upper end of the first plate 30. The cutout 35 is thereby formed in a U-shape which is opened upward with the arc portion 36 as a bottom.

The projection 39 is formed by the plate thickness of the first plate 30, and is located at a lower end of the inner peripheral surface 35a of the cutout 35. That is, the projection 39 is located in the plate thickness of the first plate 30. The projection 39 smoothly rises from the arc portion 36 of the inner peripheral surface 35a, and projects upward. The projection 39 is an example of a rotation restraint.

The first fixing portion 31 is located below the cutout 35. The first fixing portion 31 extends from the first plate 30 toward the mounting surface S, and is bent substantially parallel to the mounting surface S to be in contact with the mounting surface S. The first fixing portion 31 comprises a hole 42 through which a fixture 41 (for example, a screw) is passed, and is fixed to the mounting surface S by the fixture 41.

The pair of second fixing portions 32 and 33 are separately located on both sides of the cutout 35. In the same manner as the first fixing portion 31, each of the second fixing portions 32 and 33 extends from the first plate 30 toward the mounting surface S, and is bent substantially parallel to the mounting surface S to be in contact with the mounting surface S. Each of the second fixing portions 32 and 33 comprises a hole 42 through which a fixture 41 is passed, and is fixed to the mounting surface S by the fixture 41.

In the present embodiment, the first plate 30, the first and second fixing portions 31, 32 and 33 are formed of a single metal plate by pressing (bending). That is, the first member 21 is an integrally pressed product. Further, the cutout 35 can be formed by carrying out, for example, punching the first plate 30.

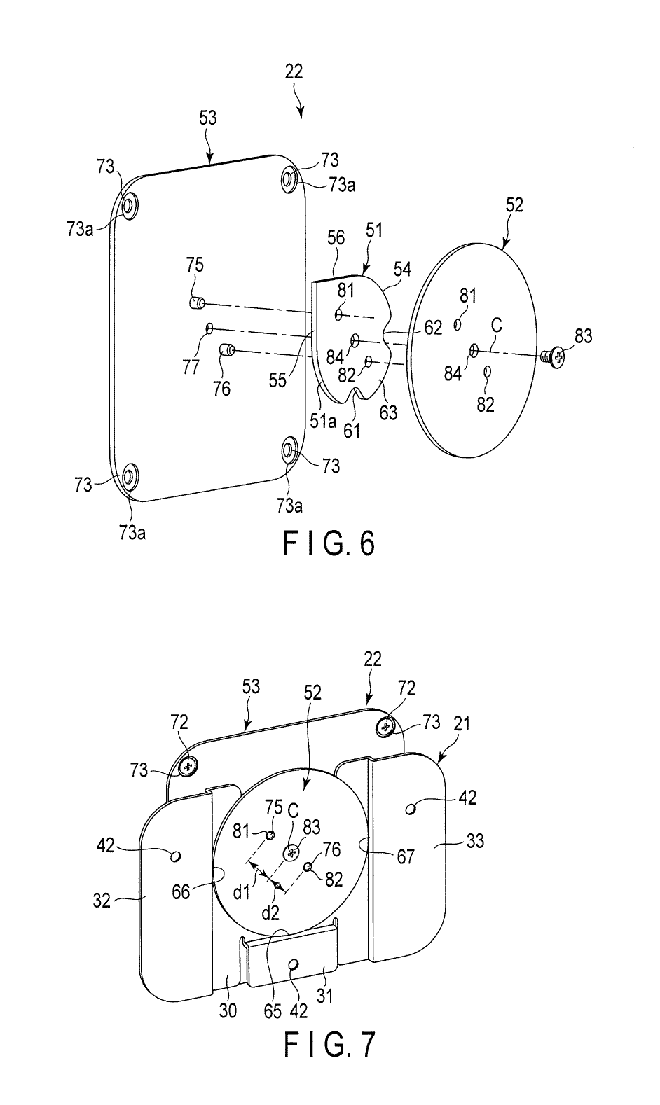

Next, the second member 22 will be described. The second member 22 is formed of, for example, three plate materials. As specifically shown in FIG. 6, the second member 22 comprises a second plate 51, a third plate 52, and a fourth plate 53.

As shown in FIG. 4 to FIG. 8, the second plate 51 has a smaller outer shape than the cutout 35 of the first plate 30, and is inserted into the cutout 35 along the inner peripheral surface 35a of the cutout 35. The plate thickness of the second plate 51 is substantially the same as or slightly larger than the plate thickness of the first plate 30. The second plate 51 is guided by the inner peripheral surface 35a of the cutout 35 to be rotatable inside the cutout 35.

An outer peripheral surface 51a of the second plate 51 comprises an arc portion 54 at least a part thereof. The radius of curvature of the arc portion 54 is substantially the same as the radius of curvature of the arc portion 36 of the cutout 35. The arc portion 54 of the second plate 51 is guided by the arc portion 36 of the cutout 35. The second plate 51 is thereby smoothly rotatable inside the cutout 35.

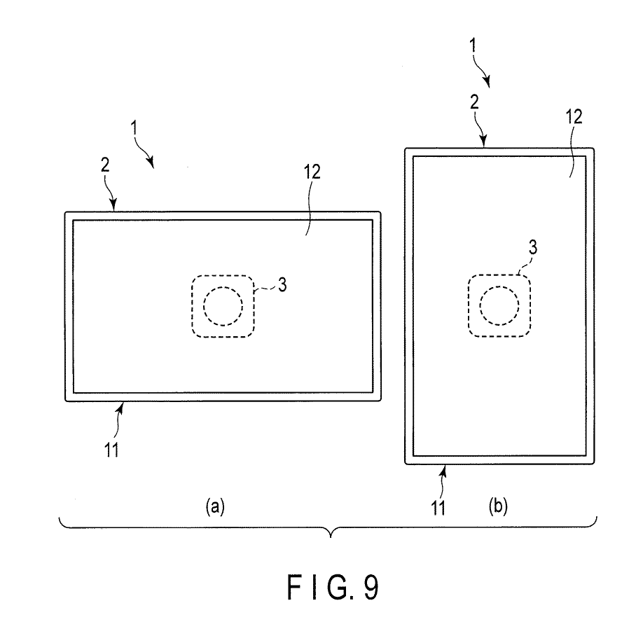

Here, the mounting unit 3 supports the video display apparatus 2 to make the video display apparatus 2 rotatable between a first orientation (FIG. 9(a)) in which it is disposed to extend horizontally and a second orientation (FIG. 9(b)) in which it is rotated 90° from the first orientation and is disposed to extend vertically.

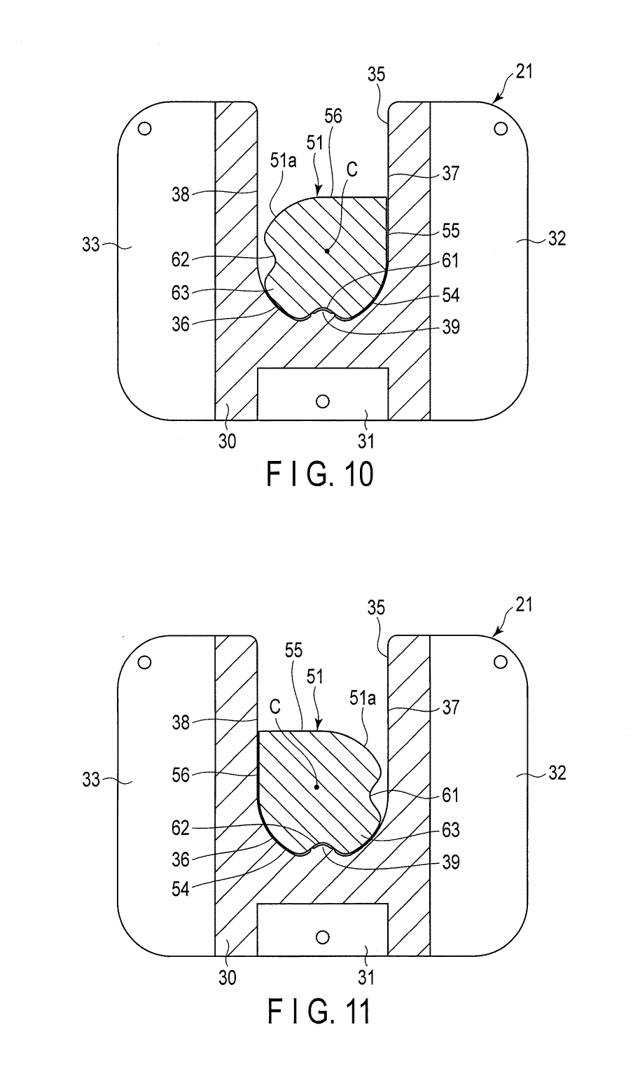

FIG. 10 shows the relationship between the cutout 35 and the second plate 51 in the above-described first orientation. As shown in FIG. 10, the outer peripheral surface 51a of the second plate 51 comprises a first receiver 61, a second receiver 62, and an overhang 63. The first receiver 61 and the second receiver 62 are depressed from the outer peripheral surface 51a to correspond to the shape of the projection 39. The second receiver 62 is provided at a position shifted 90° from the first receiver 61 with respect to a center C (rotation center) of the second plate 51.

The overhang 63 is located between the first receiver 61 and the second receiver 62, overhangs to be in contact with the inner peripheral surface 35a of the cutout 35, and forms a part of the arc portion 54. In addition, the outer peripheral surface 51a of the second plate 51 comprises a first straight line 55 and a second straight line 56 at positions separated from the arc portion 54. Each of the first straight line 55 and the second straight line 56 is formed, for example, in the shape of a plane extending in a tangential direction of the arc portion 54.

As shown in FIG. 10, the first receiver 61 engages with the projection 39 of the cutout 35 when the video display apparatus 2 is rotated to the first orientation. The second plate 51 is thereby positioned inside the cutout 35 by the projection 39, and the video display apparatus 2 is restrained from rotating in the first orientation.

Moreover, in the present embodiment, when the video display apparatus 2 is rotated to the first orientation, the first straight line 55 of the second plate 51 abuts the first portion 37 of the cutout 35. That is, the first straight line 55 of the second plate 51 comes into contact with the first portion 37 in an orientation substantially parallel to the first portion 37 of the cutout 35. The video display apparatus 2 is thereby surely restrained from rotating in a clockwise direction from the first orientation.

On the other hand, FIG. 11 shows the relationship between the cutout 35 and the second plate 51 in the above-described second orientation. As shown in FIG. 11, the second receiver 62 engages with the projection 39 of the cutout 35, when the video display apparatus 2 is rotated to the second orientation. The second plate 51 is thereby positioned inside the cutout 35 by the projection 39, and the video display apparatus 2 is restrained from rotating in the second orientation.

Moreover, in the present embodiment, when the video display apparatus 2 is rotated to the second orientation, the second straight line 56 of the second plate 51 abuts the second portion 38 of the cutout 35. That is, the second straight line 56 of the second plate 51 comes into contact with the second portion 38 in an orientation substantially parallel to the second portion 38 of the cutout 35. The video display apparatus 2 is thereby surely restrained from rotating in an anticlockwise direction from the second orientation.

Instead of the above, the mounting unit 3 may be set in the state of FIG. 11 when the video display apparatus 2 is rotated to the first orientation, and be set in the state of FIG. 10 when the video display apparatus 2 is rotated to the second orientation.

Next, the third plate 52 will be described.

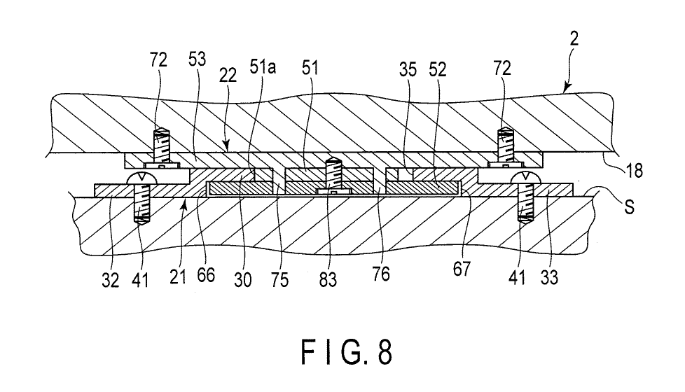

As shown in FIG. 7 and FIG. 8, the third plate 52 is, for example, a discoid plate material. A plate surface of the third plate 52 is superposed on a plate surface of the second plate 51. “Being superposed” in this specification means that plate surfaces of plates are in contact with each other.

The third plate 52 has a larger outer shape than the width W of the cutout 35. The third plate 52 is inserted into the gap g between the first plate 30 and the mounting surface S. The third plate 52 is thereby located between the first plate 30 and the mounting surface S. Because the third plate 52 is larger than the cutout 35, the second member 22 does not come out of the first member 21.

As shown in FIG. 7, the first member 21 comprises a first support portion 65 which can support a lower part of the third plate 52 in the state where the second member 22 is attached to the first member 21. The first support portion 65 is formed by, for example, a step between the first plate 30 and the first fixing portion 31. Similarly, the first member 21 comprises a pair of second support portions 66 and 67 which can each support a side of the third plate 52 in the state where the second member 22 is attached to the first member 21. The second support portions 66 and 67 are formed by, for example, steps between the first plate 30 and the second fixing portions 32 and 33.

“Can support” means, for example, allowing a certain play while restraining a movement over a predetermined mount. Here, if the third plate 52 is formed as a discoid, the first and second support portions 65, 66 and 67 still can support the third plate 52 even if the third plate 52 rotates.

Next, the fourth plate 53 will be described.

The fourth plate 53 is superposed on the second plate 51 from the opposite side to that of the third plate 52, and interposes the second plate 51 between itself and the third plate 52. A plate surface of the fourth plate 53 is superposed on a plate surface of the second plate 51. That is, the second member 22 is formed by superposing the three plate materials of the second to fourth plates 51, 52 and 53 on each other. The fourth plate 53 is a member fixed to the back cover 18 of the video display apparatus 2.

The back cover 18 of the video display apparatus 2 comprises, for example, a plurality of attachment holes 71 (see FIG. 5) according to a predetermined standard. The attachment holes 71 are, for example, attachment holes to which other wall-hung fittings are fixed. If the fourth plate 53 is provided, the mounting unit 3 of the present embodiment can be fixed to the video display apparatus 2 by using, for example, the attachment holes 71 to which other wall-hung fittings can be attached.

The fourth plate 53 comprises holes 73 through which fixtures 72 (for example, screws) are passed, at positions corresponding to the attachment holes 71. The fixtures 72 passed through the holes 73 engage with the attachment holes 71 of the back cover 18, whereby the fourth plate 53 is fixed to the video display apparatus 2. The holes 73 comprise depressions 73a (spot facing portions) which can accommodate screwheads 72a of the fixtures 72. Thus, the screwheads 72a of the fixtures 72 inserted into the holes 73 do not project from a plate surface of the fourth plate 53, or even if they project, an amount of the projection can be reduced. The plate surface of the fourth plate 53 can be thereby brought further closer to the first member 21.

In addition, as shown in FIG. 6, the fourth plate 53 comprises a plurality of projections 75 and 76 projecting toward the second plate 51 and the third plate 52, and an attachment hole 77 provided substantially at a center of the fourth plate 53. Each of the second plate 51 and the third plate 52 is provided with holes 81 and 82 through which the projections 75 and 76 of the fourth plate 53 are passed. The projections 75 and 76 are passed through the holes 81 and 82, whereby the second to fourth plates 51, 52 and 53 are integrally rotated. A distance d1 between the one projection 75 and the center C of the second plate 51 differs from a distance d2 between the other projection 76 and the center C of the second plate 51 (see FIG. 7). A mistake at the time of assembly can be thereby prevented.

Each of the second plate 51 and the third plate 52 is provided with a hole 84 through which a fixture 83 (for example, a screw) is passed, at a position corresponding to the attachment hole 77. The fixture 83 passed through the hole 84 engages with the attachment hole 77 of the fourth plate 53, whereby the second and third plates 51 and 52 are fixed to the fourth plate 53. The second to fourth plates 51, 52 and 53 are thereby superposed on each other to be integrated.

As shown in FIG. 5, the hole 84 of the third plate 52 comprises a depression 84a (spot facing portion) which can accommodates a screwhead 83a of the fixture 83. Thus, the screwhead 83a of the fixture 83 inserted into the hole 84 does not project from the plate surface of the fourth plate 53, or even if it projects, an amount of the projection can be reduced. The plate surface of the third plate 52 can be thereby brought further closer to the mounting surface S.

Finally, functions of the mounting unit 3 will be described.

As shown in FIG. 10, when the video display apparatus 2 is in the first orientation, because the first receiver 61 of the second plate 51 engages with the projection 39 of the first plate 30, the video display apparatus 2 is held in the first orientation as long as external force greater than a predetermined level does not act. On the display screen 12a, an image suitable for the first orientation (for example, a horizontally extending image) is displayed in accordance with a signal of the acceleration sensor 15.

To rotate the video display apparatus 2 from the first orientation to the second orientation, for example, force which causes the video display apparatus 2 to rotate is added without lifting up the video display apparatus 2. The video display apparatus 2 and the second member 22 are thereby naturally lifted up along the outer shape of the projection 39 of the first plate 30, and the overhang 63 of the second plate 51 gets over the projection 39 of the first plate 30.

When the overhang 63 gets over the projection 39, the second receiver 62 engages with the projection 39 by the weight of the video display apparatus 2. The video display apparatus 2 is thereby set in the second orientation. As shown in FIG. 11, when the video display apparatus 2 is in the second orientation, because the second receiver 62 of the second plate 51 engages with the projection 39 of the first plate 30, the video display apparatus 2 is held in the second orientation as long as external force greater than a predetermined level does not act. Substantially the same holds also in the case where the video display apparatus 2 is rotated from the second orientation to the first orientation.

Further, in the present embodiment, of the mounting unit 3, all the first to fourth plates 30, 51, 52 and 53 are formed of plate metals. That is, the back cover 18 of the video display apparatus 2 is thermally connected to the mounting surface S by the mounting unit 3, all or most of which is formed of metals. In addition, as described above, the mounting unit 3 is constituted mainly of four plate materials, and is very thin. Therefore, heat of the video display apparatus 2 can be effectively dissipated to the mounting surface S.

In addition, the video display apparatus 2 can be used as a portable electronic terminal by detaching the second member 22 from the first member 21. In the present embodiment, the third plate 52 is greater than the second plate 51, and the second plate 51 having a complex shape is covered by the third plate 52 having a simple shape. Thus, even in the case where the video display apparatus 2 is used while being detached from the mounting surface S, the beauty of the appearance of the video display apparatus 2 can remain unimpaired. Moreover, because the third plate 52 is located at the rearmost side, the video display apparatus 2 is easily used while being placed on a table, etc., even if the second member 22 is attached thereto. This further improves the convenience of the video display apparatus 2.

According to the above-described structure, the mounting unit 3 can be made thinner, and the video display unit 1 which excels in both convenience and design can be provided.

That is, the mounting unit 3 according to the present embodiment comprises the first member 21 fixed to the vertical mounting surface S, and the second member 22 fixed to the back cover 18 of the video display apparatus 2. The first member 21 includes the first plate 30 substantially parallel to the mounting surface S, and the cutout 35 which is provided in the first plate 30 and is opened upward. The second member 22 comprises the second plate 51 which is guided by the inner peripheral surface 35a of the cutout 35 to be rotatable inside the cutout 35, and the third plate 52 inserted between the first plate 30 and the mounting surface S, and is attachable to and detachable from the first member 21.

According to such a structure, the user can easily rotate the orientation of a screen in accordance with intended use, and a wall-hung unit which can be made thinner and less space-consuming can be provided. In the present embodiment, a gap between the back of the video display apparatus 2 and the mounting surface S can be reduced, and an example of the gap is about 8 mm.

Moreover, according to the above-described structure, because the video display apparatus 2 hung on a wall can be rotated without being detached therefrom, the convenience for the user is further increased. In addition, according to the above-described structure, because a rotational mechanism can be achieved only by a combination of the outer shapes of plate materials, the costs for components including dies can be reduced.

In the present embodiment, the plate surface of the third plate 52 is superposed on the plate surface of the second plate 51. According to such a structure, the mounting unit 3 can be made further thinner.

In the present embodiment, the inner peripheral surface 35a of the cutout 35 comprises the arc portion 36 which can guide the rotation of the second plate 51, at least a part thereof. According to such a structure, the rotation of the video display apparatus 2 can be more smoothly guided. The convenience for the user can be thereby further increased.

In the present embodiment, the first plate 30 comprises the rotation restraint provided on the inner peripheral surface 35a of the cutout 35. The second plate 51 is positioned inside the cutout 35 by the rotation restraint. According to such a structure, the rotation and the restraint of the rotation of the video display apparatus 2 can be achieved within the plate thicknesses of a plurality of plate materials. The mounting unit 3 can be thereby made further thinner.

In the present embodiment, the rotation restraint comprises the projection 39 projecting from the inner peripheral surface 35a of the cutout 35. The second plate 51 comprises the first receiver 61 which engages with the projection 39 when the video display apparatus 2 is rotated to the first orientation, and the second receiver 62 which engages with the projection 39 when the video display apparatus 2 is rotated to the second orientation. According to such a structure, the direction of the video display apparatus 2 can be held in the first orientation and the second orientation, and the convenience for the user can be further increased.

In the present embodiment, the inner peripheral surface 35a of the cutout 35 includes the first portion 37 and the second portion 38 each extending in a straight line. The outer peripheral surface 51a of the second plate 51 comprises the first straight line 55 which abuts the first portion 37 of the cutout 35 when the video display apparatus 2 is rotated to the first orientation, and the second straight line 56 which abuts the second portion 38 of the cutout 35 when the video display apparatus 2 is rotated to the second orientation. According to such a structure, in each of the first orientation and the second orientation, the rotation in a predetermined direction can be completely restrained. Thus, for example, the rotation of the video display apparatus 2 in a direction in which video is not displayed in a regular direction can be restrained, and the convenience for the user can be further improved.

In the present embodiment, the first member 21 comprises the first support portion 65 which can support the third plate 52 from the lower side, and the pair of second support portions 66 and 67 which can support the side of the third plate 52. According to such a structure, the second member 22 can be more surely supported by the first member 21, and the reliability of the mounting unit 3 can be increased.

In the present embodiment, the first member 21 comprises the fixing portion 31 which extends from the first plate 30 toward the mounting surface S and is fixed to the mounting surface S. The first support portion 65 is formed by a step between the first plate 30 and the fixing portion 31. According to such a structure, the structure of the mounting unit 3 can be further simplified, and the costs of the mounting unit 3 can be further reduced.

In the present embodiment, the second member 22 comprises the fourth plate 53 which can be fixed to the attachment holes 71 of the back cover 18 of the video display apparatus 2. According to such a structure, the mounting unit 3 which can be replaced with another wall-hung unit can be provided.

In the present embodiment, the outer shape of the third plate 52 is greater than the outer shape of the second plate 51. The third plate 52 covers the second plate 51 in the thickness direction of the video display apparatus 2 in the state where the second member 22 is detached from the first member 21. According to such a structure, the second plate 51 comprising the receivers 61 and 62 and the straight lines 55 and 56 is hidden from the outside by the third plate 52 and cannot be seen. Therefore, for example, when the video display apparatus 2 is used while being detached from a wall, the beauty of the appearance of the video display apparatus 2 can be further improved.

Next, video display units 1 according to the second to fourth embodiments will be described. Structures having the same or similar functions as or to those of the first embodiment will be given the same numbers, and explanations thereof will be omitted. In addition, the structures other than those described hereinafter are the same as those of the first embodiment.

### Second Embodiment

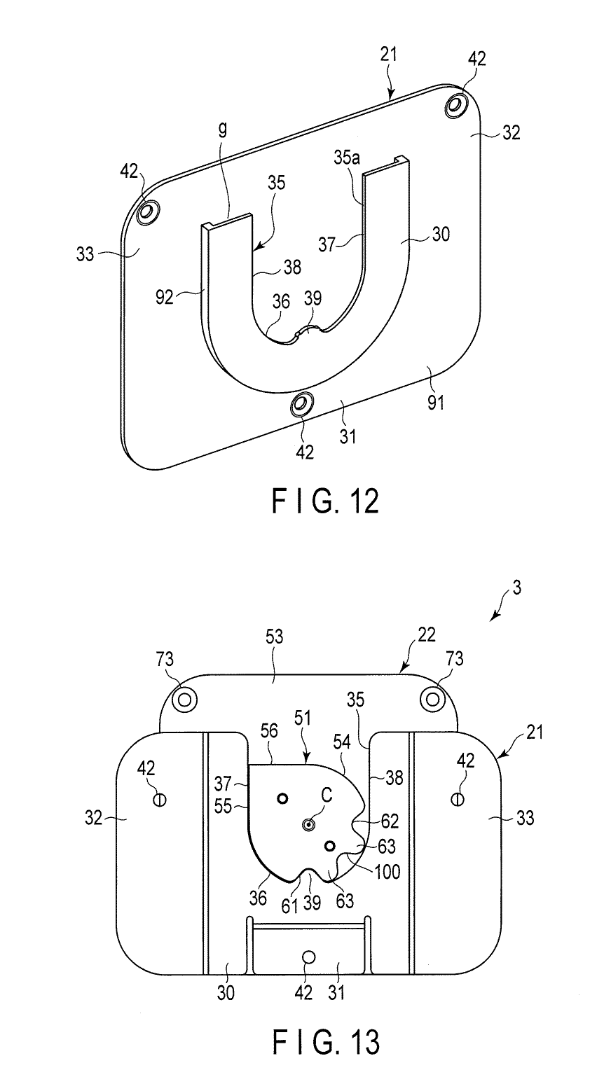

FIG. 12 shows a first member 21 according to the second embodiment. A second member 22 according to the present embodiment is the same as that of the first embodiment. The first member 21 according to the present embodiment comprises a first plate 30 and a mounting plate 91.

The mounting plate 91 has the shape of a large plate, and includes first and second fixing portions 31, 32 and 33. The first plate 30 comprises a bent portion 92. The bent portion 92 extends from an outer periphery of the first plate 30 toward the mounting plate 91. A gap g (insertion opening) into which a third plate 52 is inserted is thereby formed between the first plate 30 and the mounting plate 91. The bent portion 92 is fixed to the first plate 30 by welding, etc.

In the present embodiment, the third plate 52 is inserted into the gap g between the first plate 30 and the mounting plate 91, and is thereby located between the first plate 30 and the mounting surface S. The bent portion 92 forms first and second support portions 65, 66 and 67 which can support the third plate 52.

Also according to the mounting unit 3 having such a structure, substantially the same functions as those of the first embodiment can be achieved. According to the structure of the first embodiment, assembly work such as welding is unnecessary and the costs of materials can be reduced, as compared to the structure of the second embodiment.

### Third Embodiment

FIG. 13 shows a mounting unit 3 according to the third embodiment. A second plate 51 according to the present embodiment comprises a third receiver 100 between a first receiver 61 and a second receiver 62. An angle between the first receiver 61 and the third receiver 100 with respect to a center C of the second plate 51 is set at, for example, 45°. Similarly, an angle between the second receiver 62 and the third receiver 100 with respect to the center C of the second plate 51 is set at 45°.

The third receiver 100 engages with a projection 39 of a cutout 35 when a video display apparatus 2 is rotated 45° from a first orientation. The video display apparatus 2 is thereby restrained from rotating in an orientation oblique at 45° with respect to the first orientation.

According to the mounting unit 3 having such a structure, in addition to substantially the same functions as those of the first embodiment, the video display apparatus 2 can be held also in an oblique orientation. The mounting unit 3 with a higher degree of freedom of use can be thereby provided.

### Fourth Embodiment

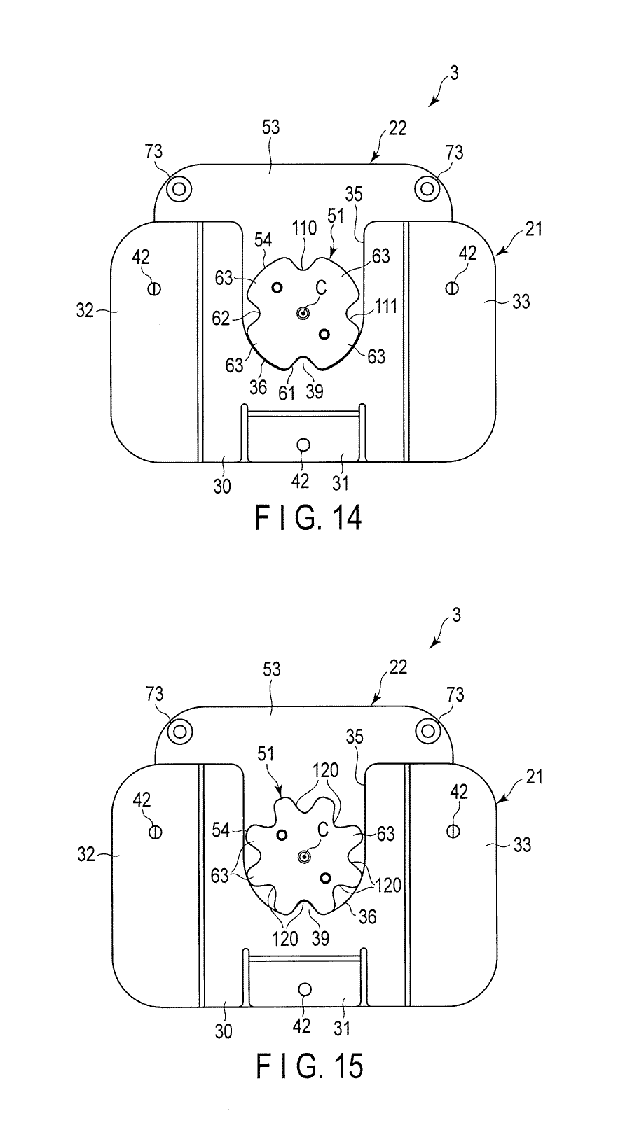

FIG. 14 shows a mounting unit 3 according to the fourth embodiment. A second plate 51 according to the present embodiment comprises a third receiver 110 and a fourth receiver 111 in addition to a first receiver 61 and a second receiver 62. The third receiver 110 engages with a projection 39 of a cutout 35, for example, when a video display apparatus 2 is rotated 180° from a first orientation. The fourth receiver 111 engages with the projection 39 of the cutout 35, for example, when the video display apparatus 2 is rotated 270° from the first orientation.

According to the mounting unit 3 having such a structure, in addition to substantially the same functions as those of the first embodiment, the video display apparatus 2 can be held in orientations at 0°, 90°, 180° and 270°. The mounting unit 3 with a higher degree of freedom of use can be thereby provided.

### Fifth Embodiment

FIG. 15 shows a mounting unit 3 according to the fifth embodiment. A second plate 51 according to the present embodiment is provided with, for example eight, receivers 120 which can engage with a projection 39 of a cutout 35 at intervals of 45°. The mounting unit 3 which can hold a video display apparatus 2 at intervals of 45° over 360° can be thereby provided.

The structures of the third to fifth embodiments can be achieved by substituting (selecting) a second plate 51 having a shape according to each of the embodiments for the second plate 51 of the mounting unit 3 of the first embodiment. In other words, the mounting unit 3 in which a second plate 51 can be changed as an option to the user's liking can be provided.

While the first to fifth embodiments have been described above, the structures of the embodiments are not limited to the above. For example, a fourth plate 53 may be omitted and a second plate 51 may be directly fixed to a back cover 18 of a video display apparatus 2.

It is to be noted that the embodiments are not restricted to those described above, and constituent elements can be modified and embodied without departing from the scope of the embodiments at an embodying stage. In addition, various embodiments can be formed by appropriately combining a plurality of constituent elements disclosed in the foregoing embodiments. For example, some constituent elements may be eliminated from all constituent elements disclosed in the embodiments. Furthermore, constituent elements in the different embodiments may be appropriately combined.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A video display unit comprising:
a video display apparatus comprising a display and a back cover covering a back of the display;
a first member comprising a first plate substantially parallel to a vertical mounting surface and a cutout which is provided in the first plate and is opened upward, the first member being fixed to the mounting surface; and
a second member comprising a second plate guided by an inner peripheral surface of the cutout to be rotatable inside the cutout and a third plate inserted between the first plate and the mounting surface, the second member being fixed to the back cover of the video display apparatus and being attachable to and detachable from the first member.

2. The video display unit of claim 1,
wherein a plate surface of the third plate is superposed on a plate surface of the second plate.

3. The video display unit of claim 1,
wherein the inner peripheral surface of the cutout comprises an arc portion for guiding rotation of the second plate at least at a part thereof.

4. The video display unit of claim 1,
wherein the first plate comprises a rotation restraint provided on the inner peripheral surface of the cutout, and
the second plate is positioned inside the cutout by the rotation restraint.

5. The video display unit of claim 4,
the rotation restraint comprises a projection projecting from the inner peripheral surface of the cutout, and
an outer peripheral surface of the second plate comprises a first receiver which engages with the projection when the video display apparatus is rotated to a first orientation, and a second receiver which engages with the projection when the video display apparatus is rotated to a second orientation.

6. The video display unit of claim 1,
wherein the inner peripheral surface of the cutout comprises a first portion and a second portion each extending in a straight line, and
an outer peripheral surface of the second plate comprises a first straight line which abuts the first portion of the cutout when the video display apparatus is rotated to a first orientation, and a second straight line which abuts the second portion of the cutout when the video display apparatus is rotated to a second orientation.

7. The video display unit of claim 1,
wherein the first member comprises a first support portion for supporting the third plate from a lower side and a pair of second support portions for supporting a side of the third plate.

8. The video display unit of claim 7,
wherein the first member comprises a fixing portion which extends from the first plate toward the mounting surface and is fixed to the mounting surface, and
the first support portion is formed by a step between the first plate and the fixing portion.

9. The video display unit of claim 1,
wherein the back cover of the video display apparatus comprises an attachment hole,
the second member comprises a fourth plate which interposes the second plate between the fourth plate and the third plate and is fixed to the attachment hole, and
a plate surface of the third plate is superposed on one plate surface of the second plate, and a plate surface of the fourth plate is superposed on an other plate surface of the second plate.

10. The video display unit of claim 1,
wherein an outer shape of the third plate is greater than an outer shape of the second plate, and
the third plate covers and hides the second plate in a thickness direction of the video display apparatus in a state where the second member is detached from the first member.

11. A mounting unit comprising:
a first member comprising a first plate substantially parallel to a vertical mounting surface, and a cutout which is provided in the first plate and is opened upward, the first member being fixed to the mounting surface; and
a second member comprising a second plate which is guided by an inner peripheral surface of the cutout to be rotatable inside the cutout and a third plate inserted between the first plate and the mounting surface, the second member being fixed to a back cover of a video display apparatus and being attachable to and detachable from the first member.
